(19) United States
(12) Patent Application Publication
(10) Pub. No.: US 2009/0174018 A1
(43) Pub. Date: Jul. 9, 2009

(54) CONSTRUCTION METHODS FOR BACKSIDE ILLUMINATED IMAGE SENSORS

(75) Inventors: Thomas Edward Dungan, Fort Collins, CO (US); Warren Farnworth, Nampa, ID (US)

Correspondence Address: RatnerPrestia, P.O. BOX 980, VALLEY FORGE, PA, 19482, US

(73) Assignee: Micron Technology, Inc., Boise, ID (US)

(21) Appl. No.: 11/971,461

(22) Filed: Jan. 9, 2008

(51) Int. Cl. H01L 21/30; H01L 31/0232

(52) U.S. Cl. 257/432; 438/458; 257/E31.127; 257/E21.211

(57) ABSTRACT

A method of constructing a backside illuminated image sensor is described. The method includes the steps of forming a semiconductor wafer, forming at least electrical contacts in the semiconductor wafer, forming, in a handle wafer separate from the semiconductor wafer, a plurality of via holes, attaching the semiconductor wafer to the handle wafer such that the via holes in the handle wafer are aligned with the respective electrical contacts on the semiconductor wafer, removing the substrate layer from the semiconductor wafer, removing at least a portion of the handle wafer to expose the plurality of via holes, filling each of the exposed via holes with a conductive material and applying a solder material to each of the exposed via holes such that the conductive material in each of the via holes is electrically connected to the solder material.

### BACKGROUND OF THE INVENTION

The present invention relates to construction methods for backside illuminated image sensors and, more particularly, to construction methods for backside illuminated image sensors using improved methods for providing mechanical integrity for the semiconductor wafer during processing and performing high temperature processing out of the presence of color filters.

Solid state image sensors, including complimentary metal oxide semiconductor (CMOS) imagers and charge-coupled devices (CCD), may be used in many different digital imaging applications to capture scenes. A solid state image sensor may include an array of pixels arranged on a semiconductor wafer. Pixel arrays may be formed on semiconductor wafers using semiconductor processing techniques such as, for example, photolithography, ion implantation, oxidation, thin film deposition and etching. When exposed to incident light to capture a scene, a photosensitive element of each pixel in the array may output a signal having a magnitude corresponding to an intensity of light at one point in the scene. The signals output from each photosensitive element may be processed to form an image representing the captured scene.

Conventional solid state image sensors may include interconnect structures, which may electrically connect the photosensitive elements with control and read-out circuitry. The interconnect structures may include layers of dielectrics and patterned metal lines and vias.

Each pixel in a solid state image sensor may have an assigned color, such as, for example, red, green or blue. Red, green and blue filters on the pixels may function to pass only light having wavelengths corresponding to the assigned color and to reflect or absorb all other wavelengths. The passed light may enter the photosensitive element whereas the reflected or absorbed light may not. Accordingly, the signal produced by each photosensitive element may have a magnitude representing an intensity of a particular color of incident light at a point in the scene.

The color filters may be formed of photoresist-type materials, which may have relatively low melting points. Specifically, the color filters may have melting points lower than the processing temperatures required during some stages of semiconductor chip processing such as, for example, formation of the interconnect layers described above. Therefore, it may be desirable that color filters are deposited after high temperature processing takes place. Alternatively, other techniques may be devised to reduce temperatures used in processing the semiconductor chips so that processing may occur after the color filters are already in place.

In one arrangement, the interconnect structures may be formed over the photosensitive elements and the color filters may be formed over the interconnect structures. This arrangement may be desirable because the color filters may be formed after high temperature processing takes place. Using this arrangement, the incident light may propagate through the interconnect structures before reaching the surface of the photodiode. Some amount of incident light may be lost due to absorption and reflection of incident light in the interconnect structures. Additionally, some amount of light intended for a given pixel may end up in neighboring pixels due to diffraction and reflection, creating undesirable optical crosstalk between the pixels.

Additional structures, such as microlens elements, may be used to direct incident light toward the surfaces of the respective photosensitive elements and away from the interconnect structures to reduce at least some of the light loss and optical crosstalk. Microlenses, however, may not sufficiently reduce the light loss and optical crosstalk and may be complex to design and manufacture.

Alternatively, the above structure may be flipped so that light may be incident on the back side of the substrate. This construction may remove the interconnect structures from the optical path to allow the incident light to enter the sensor from the substrate side. These types of imagers are typically referred to as backside illuminated. This arrangement allows for direct illumination of the photosensitive elements while still allowing the interconnect structures to be placed and processed before color filters are placed. Because the substrate may be thick enough to absorb most, if not all, of the incident light before it is able to reach the photosensitive elements, however, it may be desirable for the semiconductor substrate to be substantially thinned in order to let the incident light through.

### BRIEF DESCRIPTION OF THE DRAWINGS

These and other features, aspects, and advantages of the embodiments of the present invention described below will become more fully apparent from the following description, appended claims, and accompanying drawings in which the same reference numerals are used for designating the same elements throughout the several figures, and in which:

FIGS. 1A, 1B, 1C, 1D, 1E, 1F and 1G are wafer diagrams showing steps in a construction method for backside illuminated image sensors according to a first embodiment.

FIG. 2 is a flow chart showing the steps in the construction method for backside illuminated image sensors shown in FIGS. 1A-G.

FIGS. 3A, 3B, 3C, 3D, 3E, 3F and 3G are wafer diagrams showing steps in a construction method for backside illuminated image sensors according to a second embodiment.

FIG. 4 is a flow chart showing the steps in the construction method for backside illuminated image sensors shown in FIGS. 3A-G.

FIG. 5 is a flow chart showing the steps in a method for forming a fault line in a handle wafer according the construction method of FIGS. 1A-G and 2.

### DETAILED DESCRIPTION OF THE INVENTION

As described above, it may be necessary to thin the substrate of a backside illuminated imager to allow light to propagate through the substrate and to reach the photosensitive elements. For a silicon substrate, it may be desirable to thin the silicon to no more than a few microns, which is far below the minimum thickness required to provide mechanical integrity for wafer handling during processing. Accordingly, the embodiments of the present invention address construction methods for image sensors that provide mechanical integrity for wafer handling during processing and for high temperature processing to take place before color filters are placed.

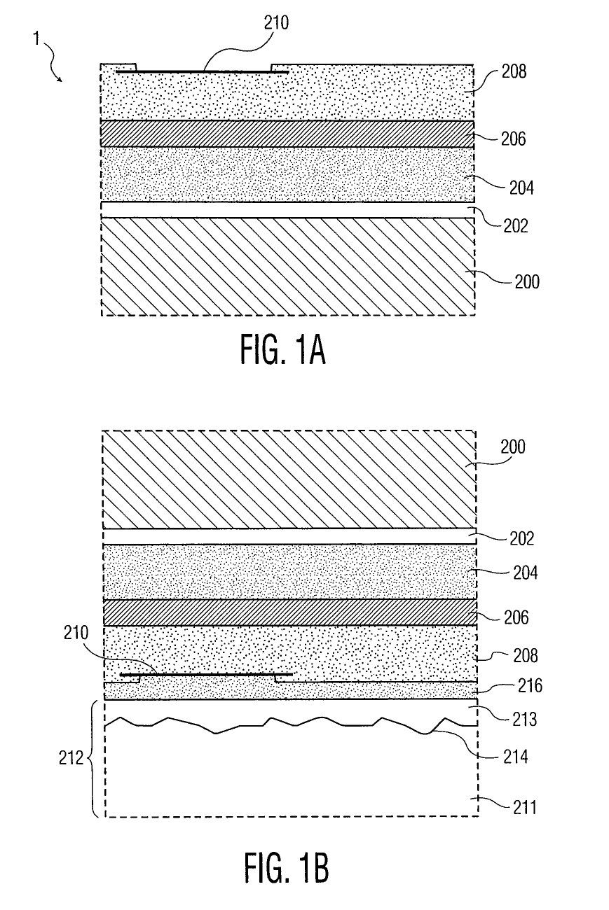

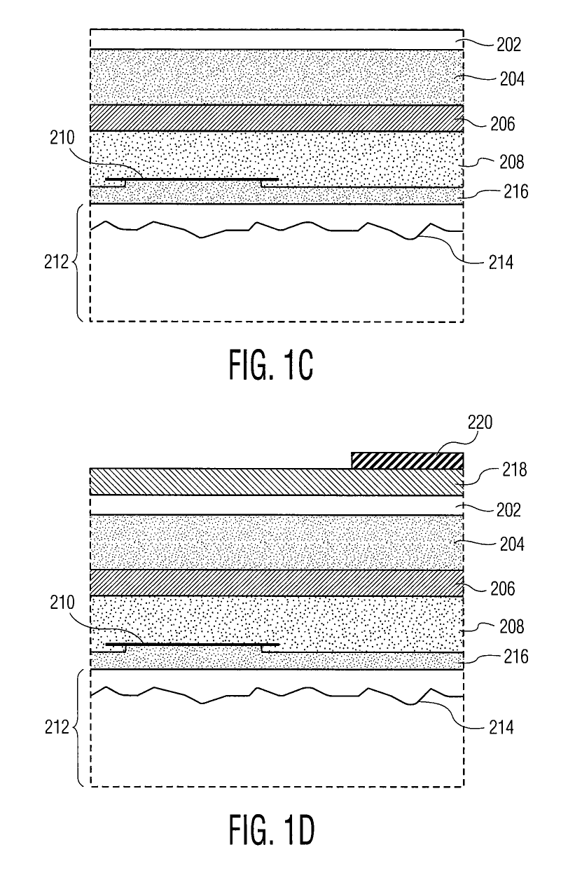

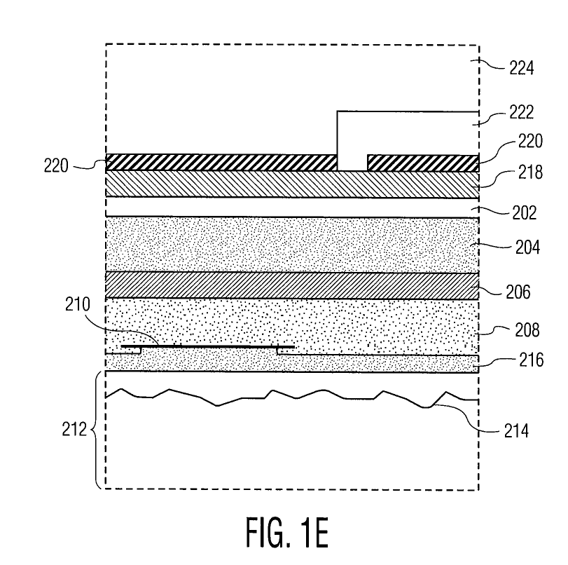

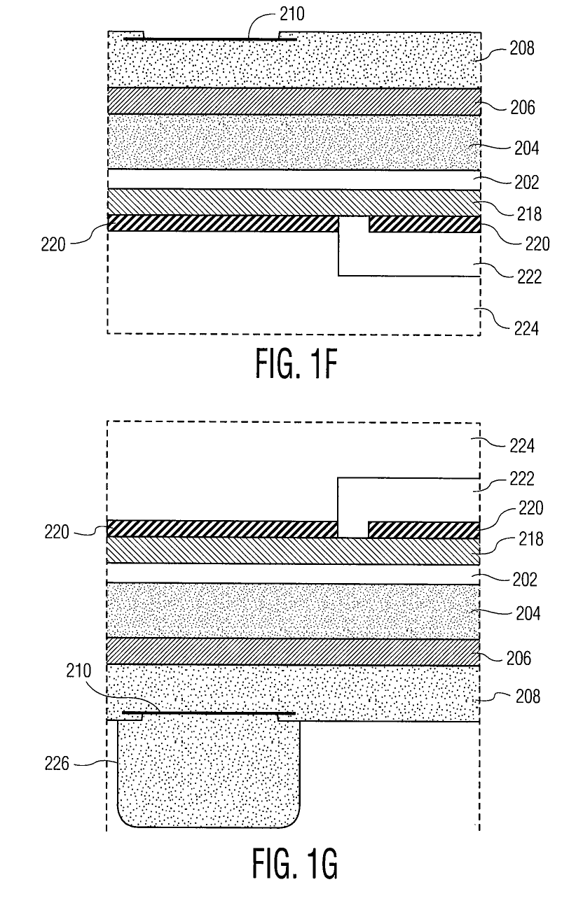

FIGS. 1A-G and 2 illustrate steps in an example construction method for backside illuminated image sensors according to a first embodiment of the present invention. The first embodiment may include using a sacrificial handle wafer to provide mechanical stability for a semiconductor wafer during first processing steps and using a cover glass to provide mechanical stability for the semiconductor wafer during second processing steps, including removal of the sacrificial handle wafer.

While the examples of the present invention are in terms of backside illuminated imagers, it is contemplated that it may be practiced with other semiconductor devices in which a thin substrate of a semiconductor material is formed on a substrate of another material.

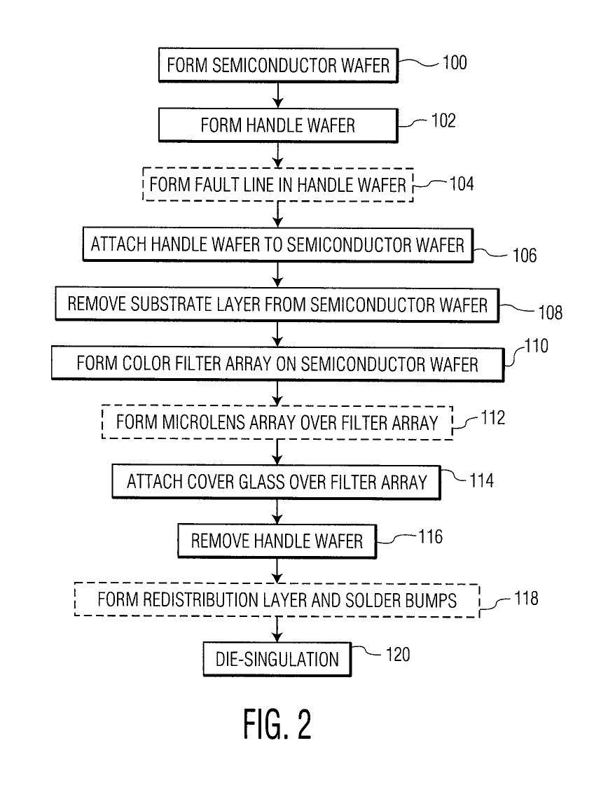

At step 100 of FIG. 2, a semiconductor wafer may be formed. An example semiconductor wafer 1 completed through interconnect formation, passivation and annealing steps is shown in FIG. 1A. Example semiconductor wafer 1 may include original substrate 200, buried etchstop 202, absorption layer 204, transistor and photodiode layer 206, interconnect structures 208 and electrical contacts 210 for multiple imagers. Example semiconductor wafer 1 may be formed by any suitable process.

At step 104, optional “smart cut” fault line 214 may be formed in a handle wafer 212. At step 106, handle wafer 212 may be attached to semiconductor wafer 1 via, for example, adhesive bonding layer 216, as shown in FIG. 1B. Adhesive bonding layer 216 may be any suitable adhesive subject to one restriction described below. If a balls on back (BOB) process is used to bond the wafers, a thermoplastic adhesive may be used. This type of adhesive, however, may limit the temperature of subsequent processing steps. In one embodiment described below, adhesive bonding layer 216 may be a temporary wafer bonding adhesive such as, for example, WaferBOND coating supplied by Brewer Science. If such a temporary bonding technique is used, the “smart cut” fault line 124 may not be needed.

Handle wafer 212 may provide mechanical support for semiconductor wafer 1 during processing. In one example embodiment, handle wafer 212 may be used to provide mechanical support for semiconductor wafer 1 during initial processing steps and may be removed after these initial processing steps have been completed.

If a temporary wafer bonding adhesive is used, the handle wafer may be separated from the semiconductor wafer by sliding the semiconductor wafer relative to the handle wafer. The temporary adhesive may then be removed using acetone IPA (isopropyl alcohol.)

If included, optional smart cut fault line 214 may ease removal of handle wafer 212. Smart cut fault line 214 may provide for a separation of handle wafer 212 into a bulk portion 211 and a thin film portion 213 so that bulk portion 211 may be easily removed, leaving only thin film portion 213 remaining after removal.

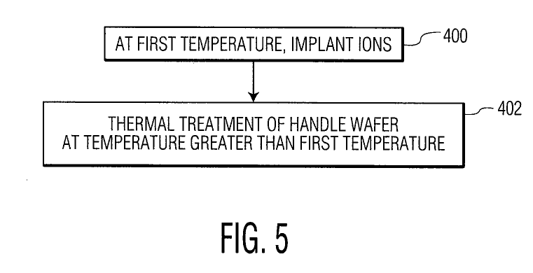

Optional smart cut fault line 214 may be formed according to steps shown in FIG. 5. At step 400, handle wafer 212 may be bombarded with ions to implant the ions in handle wafer 212. This ion implanting step may result in creation of a layer of microcavities which may separate the wafer into bulk portion 211, constituting the mass of handle wafer 212, and thin film portion 213, constituting the remaining thin film of handle wafer 212. The microcavities may form at a depth proximate to the penetration depth of the ions. Appropriate ions may include ions of rare gases or Hydrogen ions. During implantation step 400, the temperature of handle wafer 212 may be maintained at a first temperature below the temperature at which the implanted ions may escape from handle wafer 212 by diffusion.

Alternatively, internal stress may be created in the wafer using lasers and a technique similar to the Stealth Dicing technology available from Hamamatsu Photonics. This technology focuses a laser beneath the surface of the wafer. While the Stealth dicing technique forms these stress points along the edges of the dies, the technique may also be used to form stress points over an area by, for example, raster scanning the laser across the surface of the handle wafer.

At step 402, handle wafer 212 may be heat treated at a second temperature. The second temperature may be greater than the first temperature and may be sufficient to create, through a crystal rearrangement effect in handle wafer 212 and through the pressure of the microcavities, a separation between thin film portion 213 and bulk portion 211. This second temperature may be, for example, 500 degrees Celsius for silicon. This separation may simplify mechanical removal of handle wafer 212 from wafer 1. That is, the separation may permit thin film portion 213 and bulk portion 211 to be pried apart, eliminating any need to grind the handle wafer down to remove it. Also, because bulk portion 211 of handle wafer 212 may be removed almost entirely intact, it may be re-used.

Even after the heat treatment, the handle wafer 211 provides sufficient support to semiconductor wafer 1 to allow conventional semiconductor processing steps to be performed, as described below.

It may be desirable to conduct heat treating step 402 before the color filters are placed on the wafer 1. Handle wafer 212 separated into thin film portion 213 and bulk portion 211 may provide sufficient mechanical support for processing semiconductor wafer 1. Accordingly, this step may take place before color filters are laid. Specifically, this step may take place after handle wafer 212 is attached to semiconductor wafer 1 and before original substrate 202 is removed, as described below. Alternatively, this step may take place after original substrate 202 is removed and before color filters 218 are attached, as described below. Further, because handle wafer 212 may be formed separately from semiconductor wafer 1, heat treating step 402 may also be conducted before semiconductor wafer 1 is attached to handle wafer 212.

After handle wafer 212 is attached to semiconductor wafer 1, handle wafer 212 may be used to provide mechanical support for semiconductor wafer 1 during further processing. Using handle wafer 212 to provide mechanical support, at step 108, original substrate 200 may be removed from semiconductor wafer 1, as shown in FIG. 1C. As shown in FIG. 1C, in one example embodiment, original substrate 200 may be removed down to etchstop 202. In this way, substantial thinning of original substrate 200 may be provided to allow a sufficient amount of the incident light to reach the photosensitive elements disposed in layer 206.

One example method of forming etchstop 202 and removing substrate 200 down to etchstop 202 may be a bond-and-etch back technique. Bond-and-etch back includes bonding wafer 1 to handle wafer 212, grinding wafer 1 from the back surface to thin substrate 200 from wafer 1 and then chemically etching the remaining portion of substrate 200 down to etchstop 202. If desirable, etchstop 202 may also be removed at this point by chemical etching. One example suitable etchstop for use with such bond-and-etch back technique may include a heavily boron-doped etch stop layer. Any suitable etchstop may, however, be used as etchstop 202. Also, any other suitable methods of forming etchstop 202, such as silicon on insulator (SOI) and Silicon Nitride epitaxial layer methods, may be used.

After substrate 200 is removed, optional passivation and annealing of semiconductor wafer 1 may be performed (not shown). Then, at step 110, color filter array 218 may be formed on semiconductor wafer 1, as shown in FIG. 1D. Color filter array 218 may include an array of color filters, each color filter corresponding to a pixel formed on semiconductor wafer 1. In this way, each pixel of each imager formed on semiconductor wafer 1 may have a color filter of color filter array 218 disposed over it. Color filter array 218 may include different ones of single color filters adapted to pass one band of wavelengths of the incident light. Thus, each pixel exposed to incident light may produce a signal proportional to the intensity of a particular color of light.

At step 112, optional microlens array 220 may be formed over color filter array 218, as shown in FIG. 1D, leaving an air gap between the color filter array and the microlens array. Microlens array 220 may include an array of microlenses, each microlens corresponding to a pixel formed on semiconductor wafer 1. In this way, each pixel may have a microlens of microlens array 220 disposed over it. The microlenses may be included if, for example, it is desirable to focus the incident light onto each pixel. They may not be necessary, however, due to the backside illuminated construction. That is, because the interconnect structures may be formed below the photosensitive elements, it may not be necessary to include microlenses over the pixels to direct the incident light toward each pixel and away from the interconnect structures.

IR alignment may be used to align the filters with the buried photodiodes. It may also be possible to create visible alignment marks on the semiconductor wafer during manufacture of the semiconductor wafer itself, which may be used to align the filters with the buried photodiodes.

At step 114, cover glass 224 may be formed over color filter array 218 or over microlens array 220, if provided. Cover glass 224 may be attached using at least two different methods. First, cover glass 224 may be attached directly to semiconductor wafer 1. Here, a passivation layer (not shown) may be formed on color filter array 218 and the outer edges of each imager. Cover glass 224 may then be attached directly to the passivation layer.

Second, as shown in FIG. 1E, cover glass 224 may be attached only around the outer edges of each imager formed on semiconductor wafer 1. In this way, cavity 222 may be formed between a top surface microlens array 220 and a bottom surface of cover glass 224 for each imager, as shown in FIG. 1E. The cavity beneath the cover glass may be useful when microlens array 220 is used to ensure that the microlenses properly diffract light, the surface of the lens is ideally surrounded with a material (e.g. air) having an index of refraction that is less than the index of refraction of the lens material. Alternatively, cavity 22 may be formed between a top surface of color filter array 218 and a bottom surface of cover glass 224. In either method, cover glass 224 may be attached using an adhesive, thus permanently attaching cover glass 224 to semiconductor wafer 1. The cavity may be filled with an optical gap fill material (i.e., a material having an index of refraction less than the cover glass and less than the lens material) to provide further support for the wafer.

Permanently attached cover glass 224 may serve at least two functions. First, cover glass 224 may protect the color filters, microlenses and photosensitive elements disposed under it from particles in the ambient air during the remaining processing steps. Second, cover glass 224 may be used to provide mechanical support for semiconductor wafer 1 when the handle wafer 212 is removed.

The adhesive used to permanently bond cover glass 224 to semiconductor wafer 1 may be any suitable adhesive. However, the adhesive used should have different material characteristics than the adhesive used in adhesive bonding layer 216, which was used to bond handle wafer 212 to semiconductor wafer 1. This is because adhesive bonding layer 216 may be etched or otherwise processed to expose electrical contacts 210 when handle wafer 212 is subsequently removed and, if an adhesive having the same material characteristics were used for both applications, any processing technique used to remove adhesive bonding layer 216 may also affect the adhesive bonding cover glass 224 to semiconductor wafer 1. In one embodiment, an ultraviolet cured and set adhesive may used as the adhesive to permanently bond cover glass 224 to semiconductor wafer 1. Because ultraviolet radiation is used to cure and set the adhesive instead of, for example, heat, it may be used in the presence of the filters. Additionally, by using ultraviolet radiation to cure and set the adhesive as opposed to, for example, using a solvent, contamination of the glass due to outgas may be prevented.

To prevent warpage of the permanent cover glass, the gap between the color filter array and the microlens array (if included) may be pressurized during step 114 so that the pressure in the wafer is ambient at ambient temperature.

Because the cover glass may be used later to provide mechanical support for the wafer during processing, it may be desirable to protect the cover glass. For this purpose, a high modulus polyimide film such as, for example, the Kapton® film provided by Dupont, may be used. The film may cover the surface of the glass and may protect the glass from damage due to contact with a surface, chemicals contacting the glass and high temperature processing.

Using cover glass 224 for support, at step 116, handle wafer 212 may be removed, as shown in FIG. 1F. If an optional smart cut fault line is not formed in handle wafer 212 and a temporary wafer bonding coating was not used to bond handle wafer 212 to semiconductor wafer 1, handle wafer 212 may be removed by grinding and then polishing rough edges to smooth using wet etch or other methods. If, however, optional smart cut fault line is formed in handle wafer 212, a simple splitting tool may be applied to fault line 214 to permanently wedge apart and remove bulk portion 211 from thin film portion 213. Alternatively, as addressed above, a laser may be used to create stresses in the handle wafer at a desired depth (e.g., at a depth corresponding to the smart cut fault line). Tensile stress caused by the stresses may cause the wafer to separate at the fault line. Thin film portion 213 may then be polished to smooth using wet etch or other methods. Using smart cut techniques, handle wafer 212 may be easily removed and bulk portion 211 may be preserved for re-use as a handle wafer in the manufacture of other image sensors. If a temporary wafer bonding coating was used to bond handle wafer 212 to semiconductor wafer 1, handle wafer 212 may be slid away from semiconductor wafer 1 and adhesive bonding layer 216.

After handle wafer 212 is removed, adhesive bonding layer 216 may be removed to expose electrical contacts 210 using wet etch or other suitable methods. If wet etch is used, an etchant is desirably chosen to remove adhesive bonding layer 216 without removing the adhesive used to bond cover glass 224 to semiconductor wafer 1. If a temporary wafer bonding coating was used to bond handle wafer 212 to semiconductor wafer 1, the material may be removed using, for example, acetone isopropyl alcohol (Acetone-IPA).

It may be desirable, at this point, to provide additional support for the remaining structure, which may be between 1.5 and 15 microns thick. This may be done, for example, by providing a thick polymer coating (e.g., thick polymer coating provided by HD Microsystems) on the surface of wafer 1 exposed when handle wafer 212 and adhesive bonding layer 216 are removed. A thick polymer film may be deposited on the exposed surface of the wafer. Tension may be applied to the film to align rods in the polymer coating creating a material having a coefficient of thermal expansion (CTE) that matches the CTE of the support layer on the previously exposed surface of the wafer at least in the x, y plane.

At step 118, optional flip-chip processing may be performed by forming a redistribution layer (not shown) and solder bumps 226, so as to electrically connect solder bumps 226 with exposed electrical contacts 210, as shown in FIG. 1G. The solder bumps may subsequently be used to electrically connect the image sensor chip with external electronic devices. Flip-chip processing may provide at least one distinct advantage in that it may reduce undesirable capacitance on chip-to-board connection. Electrical contacts 210 may be disposed only around the perimeter of each chip of semiconductor wafer 1. Alternatively, electrical contacts 210 may be area array contacts distributed across the front surface of each chip. If area array contacts are used, this may further reduce undesirable capacitance on chip-to-board connection.

If no thick polymer coating is provided on the surface of wafer 1 that is exposed when handle wafer 212 and adhesive bonding layer 216 are removed, an electrolytic plating process may be used to form the bumps. If a thick polymer coating is provided, via holes may be formed in the thick polymer coating and filled with a conductive material. An electrolytic plating process may be used to form the conductive traces. If a thick polymer coating is provided, an ultraviolet exposed and cured polymer may be used to form the traces using printing, plating or sputtering. Because the wafer is supported by the thick polymer coating, the wafer may maintain its integrity under the vacuum provided in a sputter chamber and, therefore, sputtering may be used to deposit the traces.

At step 120, the wafer may be diced into individual dies or imagers. Before dicing, for example, wide gaps may be formed between individual imagers using a dry etch. A blade (e.g., a nickel diamond standard cutting blade) may then be used to scribe the wafer, cutting only partially through the wafer. A wet etch may then be used (e.g., Tetra-Methyl Ammonium Hydroxide (TMAH) or Potassium Hydroxide (KOH) to remove inclusions created by the blade. Die singulation may then be performed using dicing tape along with a narrower blade or a smaller collimated laser. The silicon edge of each individual die may be coated to provide a light seal. Alternatively, such light seal may be created for each singulated die by using a partial saw and opaque polymer fill followed by a re-saw or laser reduced cut width. The stealth dicing technique, described above, may also be used for die singulation.

In the final construction, each sensor package may be configured to receive incident light through a top surface of cover glass 224, as shown in FIG. 1G. Oriented this way, interconnect structures 208 may not be disposed between photodiodes in transistor and photodiode layer 206 and the incident light impinging on the photodiodes through cover glass 224. Accordingly, a backside illuminated image sensor may be formed while preserving mechanical integrity of the semiconductor wafer and preserving the optical properties of the color filters.

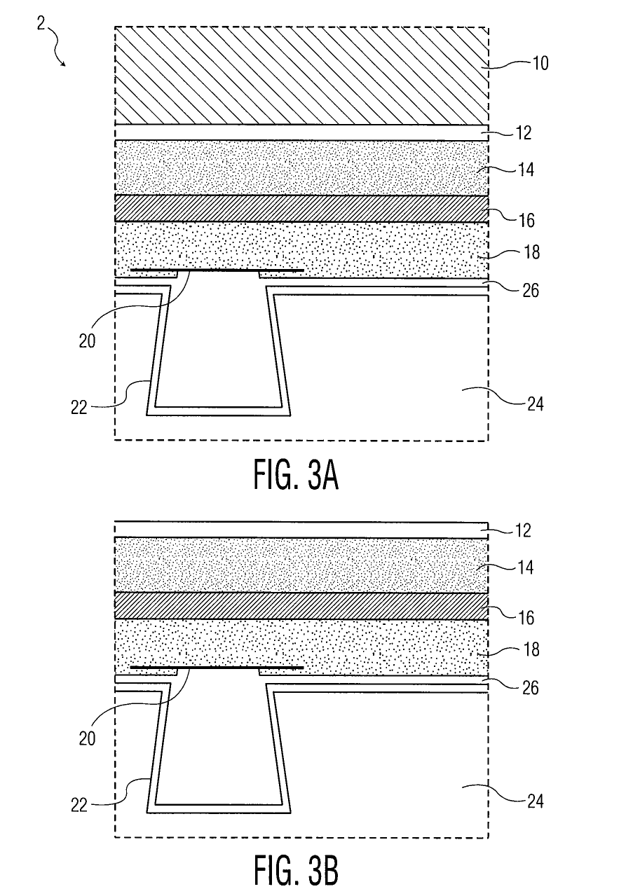

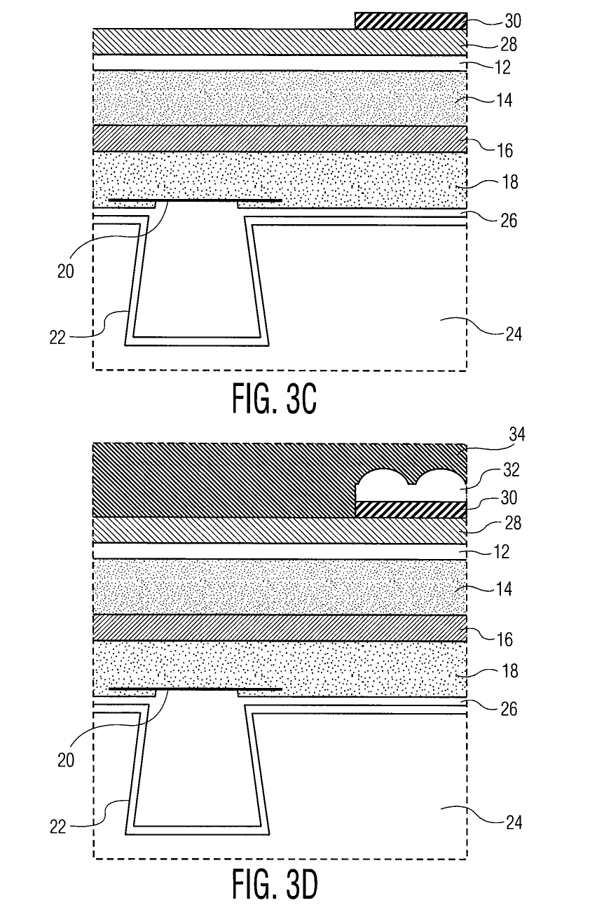

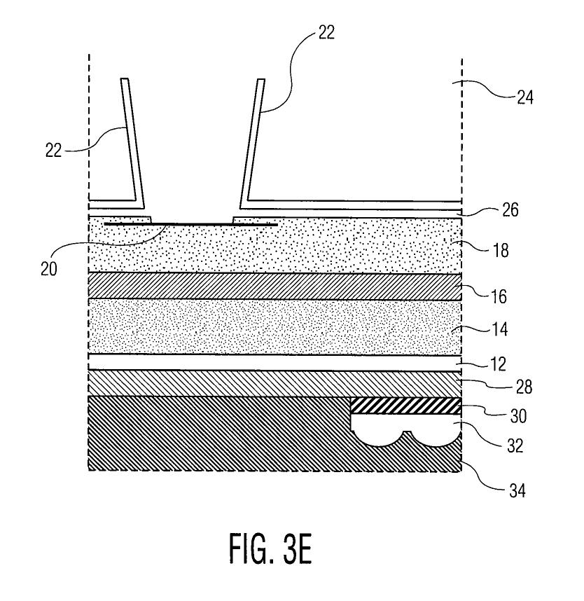

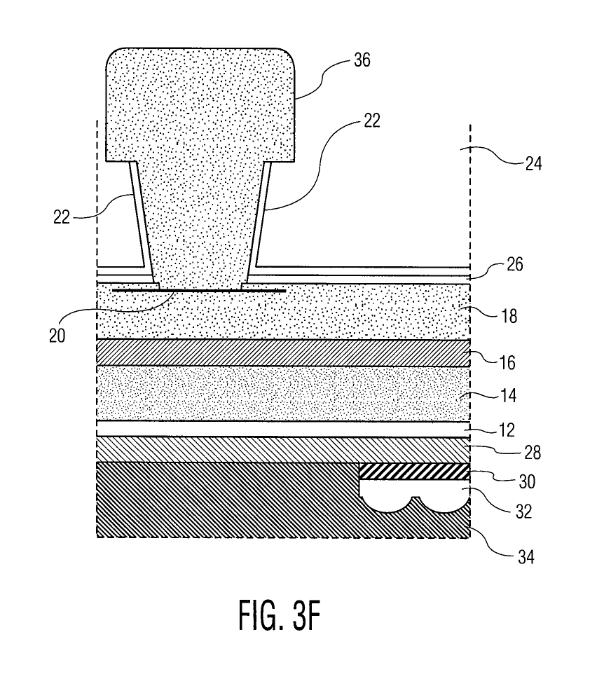

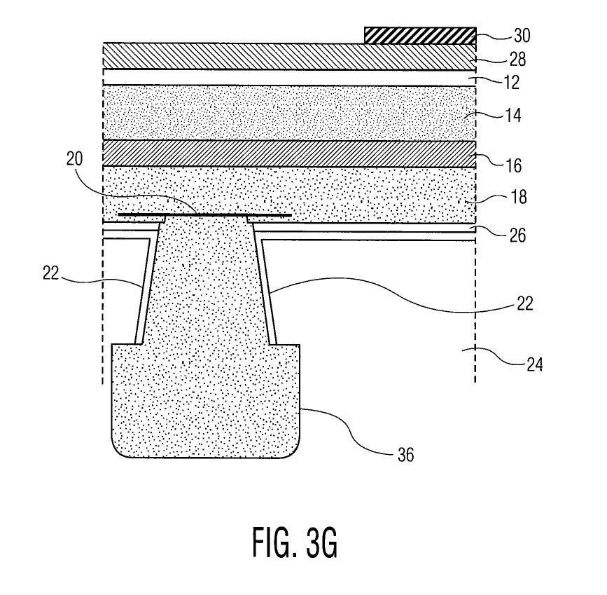

FIGS. 3A-G and 4 illustrate steps in an example construction method for backside illuminated image sensors according to a second embodiment of the present invention. The second embodiment may include using a handle-wafer with pre-formed via holes to provide mechanical stability for a semiconductor wafer while thinning the semiconductor substrate. In this example embodiment, the handle wafer may be permanently attached to the semiconductor wafer because the pre-drilled via holes may provide an electrical connection between the interconnect structures and external electrical devices. In this way, the handle wafer may be used to provide mechanical integrity for the semiconductor wafer throughout the entire manufacturing process and, accordingly, the cover glass may not be needed to provide mechanical integrity during later processing steps.

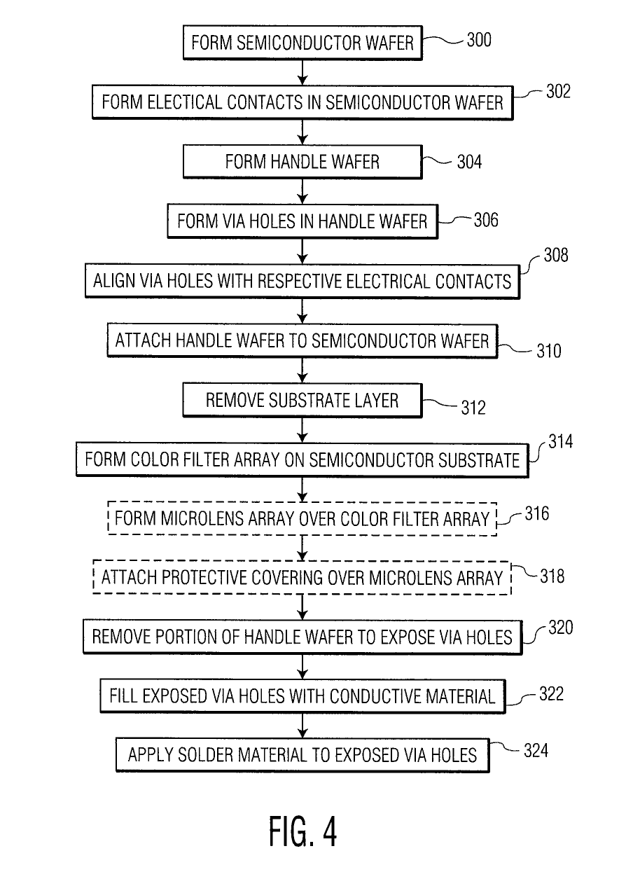

At step 300 of FIG. 4, a semiconductor wafer may be formed. As shown in FIG. 3A, the semiconductor wafer 2 may have the same or a similar structure as semiconductor wafer 1 of the first embodiment. An example semiconductor wafer completed through interconnect formation, passivation and anneal is shown in FIG. 1A attached to handle wafer 24. The example semiconductor wafer may include original substrate 10, buried etchstop 12, absorption layer 14, transistor and photodiode layer 16 and interconnect structures 18. After semiconductor formation, at step 302, electrical contacts 20 may be formed in the semiconductor wafer.

At step 306, partial thickness via holes 22 may be formed in handle wafer 24, which is separate from semiconductor wafer 2. Steps 304 and 306 result in a handle wafer 24 with pre-formed partial thickness via holes. Each of the via holes may be formed so as to extend from a top surface of the handle wafer partially through the handle wafer toward a bottom surface of the handle wafer. Further, each of the via holes may be formed in a position on the handle wafer corresponding to a respective one of the electrical contacts on the semiconductor wafer. At this stage, the openings of the via holes may not be exposed from the handle wafer. They may be exposed later when the handle wafer is thinned, as described below. Alternatively, the via holes may be pre-formed in the handle wafer and may extend through the entire thickness of the handle wafer. They may be filled before the handle wafer is attached to the semiconductor wafer. The conductive traces and plating may also be in place before the handle wafer is attached to the semiconductor wafer.

At step 308, handle wafer 24 with pre-formed partial thickness via holes 22 already formed in it may be disposed over the semiconductor wafer. Here, via holes may be aligned with respective electrical contacts 20 using, for example, an IR alignment technique. At step 310, after the appropriate alignments have been made, handle wafer 24 may be attached to the semiconductor wafer using, for example, Benzocylobutene (BCB), a curable polymer or polimide or any suitable adhesive. If the via holes have been pre-formed and the trace work and plating are in place, an interconnect may be formed between the vias and the respective electrical contacts when the handle wafer is attached to the semiconductor wafer while both the handle wafer and semiconductor wafer are at their thickest.

The via holes may be formed in the handle wafer by, for example, dry plasma etching or other suitable processes. For this reason, forming the via holes in the handle wafer before attaching the handle wafer and before color filters are attached to the semiconductor wafer may be advantageous because high temperature dry plasma etching or other high temperature processes may take place away from the color filters. Using a handle wafer with pre-formed partial thickness via holes to provide mechanical integrity for the semiconductor wafer during processing may provide several additional advantages. First, the handle wafer may remain attached to the semiconductor wafer throughout the entire manufacturing process. Second, the handle wafer may allow for use of via holes to provide electrical connectivity between interconnect structures formed in the semiconductor wafer and external electrical components in a solid state image sensor that includes relatively low melting temperature color filters.

After handle wafer 24 with pre-formed via holes 22 is attached to the semiconductor wafer 2, it may be used to provide mechanical support for the semiconductor wafer during further processing. Using handle wafer 24 to provide mechanical support, at step 312, original substrate 10 may be removed from the semiconductor wafer, as shown in FIG. 3B. In one example embodiment, original substrate 10 may be removed down to etchstop 12. In this way, substantial thinning of original substrate 10 may be provided to allow a sufficient amount of the incident light to reach the photosensitive elements disposed in layer 16. As in the first embodiment, etchstop 12 may be formed and substrate 10 may be removed down to etchstop 12 using any suitable technique, such as the bond-and-etch back technique described above.

After substrate 10 is removed, optional passivation and annealing of the semiconductor wafer may be performed (not shown). Then, at step 314, color filter array 28 may be formed on the semiconductor wafer, as shown in FIG. 3C. Color filter array 28 may include multiple color filters, each color filter corresponding to a pixel formed on the semiconductor wafer 2. In this way, each pixel of each imager on the wafer may have a color filter of color filter array 28 disposed over it. Color filter array 28 may include different ones of single color filters adapted to pass one band of wavelengths of the incident light. Thus, each pixel exposed to incident light may produce a signal proportional to the intensity of a particular color of light.

IR alignment may be used to align the filters with the buried photodiodes. It may also be possible to create visible alignment marks on the semiconductor wafer during manufacture of the semiconductor wafer itself, which may be used to align the filters with the buried photodiodes.

At step 316, optional microlens array 30 may be formed over color filter array 28, as shown in FIG. 3C. Microlens array 30 may include an array of microlenses, each microlens corresponding to a pixel of an imager formed on the semiconductor wafer. Microlens array 30 may be included if, for example, it is desirable to focus the incident light onto each pixel. This may not, however, be necessary, due to the backside illuminated construction. That is, because the interconnect structures may be formed below the photosensitive elements, it may not be necessary to include microlenses over the pixels to direct the incident light toward each pixel and away from the interconnect structures.

At step 318, optional protective covering 34 may be formed over color filter array 28 or over microlens array 30, if used. Optional covering 34 may be a cover glass, such as cover glass 224 described above with respect to the first embodiment. If such cover glass is used, it may be permanently attached using any of the methods described above with respect to the first embodiment or may be temporarily attached using any suitable method. Alternatively, because a permanent cover glass is not needed to provide mechanical integrity during processing, any temporary protection, such as protective tape, may be used as optional covering 34, as shown in FIG. 3D When the tape is removed, after the processing is complete, there may be some adhesive residue on the color filter array 28 or microlens array 30 which would need to be removed. Use of the cover glass may avoid this step. Here, the protective covering may be used to protect the color filters and optional microlenses when the semiconductor wafer is flipped so that the color filters and optional microlenses are placed on a work surface during some of the subsequent steps.

If a permanent cover glass is used, any suitable adhesive may be used. The restrictions described with respect to the first embodiment may not be applicable here because handle wafer 24 is not removed from the semiconductor wafer.

At step 320, if the via holes have not been pre-filled, the semiconductor wafer may be flipped so that the color filters and optional microlenses may be placed on a work surface. Then, handle wafer 24 may be thinned at least until openings of pre-formed via holes 22 are exposed from handle wafer 24, as shown in FIG. 3E. Thinning may be performed by any suitable method such as, for example, grinding.

At step 322, exposed via holes 22 may be filled with a conductive material, as shown in FIG. 3F. In this way, via holes 22 may form an electrical connection with their respective aligned electrical contacts 20. Electrical contacts may be disposed only around the perimeter of each chip of the semiconductor wafer. Alternatively, electrical contacts 20 may be area array electrical contacts. Area array electrical contacts may reduce undesirable capacitance on chip-to-board connections.

At step 324, optional flip-chip processing may be performed by, for example, applying solder material to the exposed ends of exposed via holes 22 to form, for example, solder bumps 36, as shown in FIG. 3F. In this way, solder bumps 36 may be electrically connected through via holes 22 to the respective electrical contacts 20. During connection of the solid state image sensor to external electrical devices, the sensor package may be flipped, as shown in FIG. 3G. Then, example solder bumps 36 may be aligned with electrodes or other conductive devices disposed on the external electrical devices not shown), thus forming an electrical connection between the electronic elements disposed in the image sensor and electronic elements disposed in the external device (not shown). Flip-chip processing may provide at least one distinct advantage in that it may further reduce undesirable capacitance on chip-to-board connections.

An ultraviolet exposed and cured polymer may be used to form the conductive traces using printing, plating or sputtering. Because the wafer is supported by the handle wafer, the wafer may maintain its integrity under the vacuum provided in a sputter chamber and, therefore, sputtering may be used to deposit the traces.

In FIGS. 3A-3G, layer 26 is disposed between pre-formed via holes 22 and interconnect structures 18 and electrical contacts 20. Layer 26 may be an insulating layer, such as an oxide. Although not shown, an insulating material may also be disposed where solder bump 36 extends over the semiconductor wafer and in via holes 22 before they are filled with the conductive material. The insulating material may be deposited by top side methods. It may also be possible to make a high integrity insulator by thermally oxidizing the semiconductor wafer before color filter array 28 is attached to the semiconductor wafer. This may be especially desirable for forming layer 26 and for forming the insulating material in the via holes. Including an insulating material as described above may be desirable to prevent stray leakage between bumps.

After the exposed via holes are filled and/or after solder bumps are formed, any temporary protection for color filters and optional microlenses attached in step 318 may be removed. If no protection was attached or if a cover glass was attached, this step may be skipped.

The wafer may then be diced into individual dies or imagers. Before dicing, for example, wide gaps may be formed between individual imagers using a dry etch. A blade (e.g., a nickel diamond standard cutting blade) may then be used to scribe the wafer, cutting only partially through the wafer. A wet etch may then be used (e.g., Tetra-Methyl Ammonium Hydroxide (TMAH) or Potassium Hydroxide (KOH) to remove inclusions created by blade. Die singulation may then be performed using a narrower blade, a smaller collimated laser or dicing tape. The silicon edge of each individual die may be coated to provide a light seal at the perimeter of each singulated die. Alternatively, such light seal may be created for each singulated die by using a partial saw and opaque polymer fill followed by a re-saw or laser with a reduced cut width.

In the final construction, each sensor package may be configured to receive incident light through the bottom surface of the semiconductor wafer (i.e., the surface on which color filters and optional microlenses have been attached). Oriented this way, interconnect structures 18 may not be disposed between photodiodes in transistor and photodiode layer 16 and the incident light impinging on the photodiodes through the top surface of the semiconductor wafer. Accordingly, a backside illuminated sensor may be formed while preserving mechanical integrity of the semiconductor wafer and preserving the optical properties of the color filters.

While example embodiments of the invention have been shown and described herein, it will be understood that such embodiments are provided by way of example only. Numerous variations, changes and substitutions will occur to those skilled in the art without departing from the invention. Accordingly, it is intended that the appended claims cover all such variations as fall within the scope of the invention.

What is claimed:

1. Method of manufacturing a thin semiconductor device, the method comprising the steps of:
forming a semiconductor wafer having a substrate layer and an electronics layer, wherein the substrate layer is thicker than the electronics layer, the substrate layer extends to a bottom surface of the semiconductor wafer and the electronics layer includes a plurality of electrical contacts that extend to a top surface of the semiconductor wafer;
forming, in a handle wafer separate from the semiconductor wafer, a plurality of via holes, each of the via holes extending from a top surface of the handle wafer partially through the handle wafer toward a bottom surface of the handle wafer and corresponding in position on the handle wafer to a respective one of the plurality of electrical contacts on the semiconductor wafer;
attaching the top surface of the semiconductor wafer to the top surface of the handle wafer such that the via holes in the handle wafer are aligned with the respective electrical contacts on the semiconductor wafer;
removing the substrate layer from the semiconductor wafer;
removing at least a portion of the handle wafer from the bottom surface of the handle wafer to expose the plurality of via holes; and
filling each of the exposed via holes with a conductive material to form a conductive channel from the respective electrical contact in the at least one via hole.

2. The method of manufacturing a thin semiconductor device of claim 1, further comprising the step of attaching an array of color filters to a bottom surface of the semiconductor wafer after the substrate is removed from the semiconductor wafer.

3. The method of manufacturing a thin semiconductor device of claim 1, wherein the attaching step includes attaching the handle wafer to the semiconductor wafer using an adhesive selected from a group consisting of benzocylobutene, a curable polymer or a curable polyimide.

4. The method of manufacturing a thin semiconductor device of claim 3, wherein the step of forming the plurality of via holes in the handle wafer includes using dry plasma etch processing.

5. The method of manufacturing a thin semiconductor device of claim 3, further comprising the steps of:
covering the array of color filters with a temporary protection layer,
flipping the semiconductor wafer so that the array of color filters is placed on a work surface, wherein the conductive material is applied to each of the exposed via holes after the semiconductor wafer is flipped, and
removing the temporary protection layer after the conductive material is applied to each of the exposed via holes.

6. The method of manufacturing a thin semiconductor device of claim 1, further comprising the step of forming an insulating layer on the top surface of the semiconductor wafer by thermally oxidizing the top surface of the semiconductor wafer before attaching the top surface of the handle wafer to the bottom surface of the semiconductor wafer,
wherein the insulating layer is formed before the color filters are attached to the bottom surface of the semiconductor wafer remaining after the substrate layer is removed from the semiconductor wafer.

7. The method of manufacturing a thin semiconductor device of claim 6, further comprising the step of forming an insulating material on interior surfaces of the via holes by thermally oxidizing the interior surfaces of the via holes before the via holes are filled with the conductive material.

8. A method of manufacturing a thin semiconductor device, the method comprising the steps of:
forming a semiconductor wafer having a substrate layer and an electronics layer, wherein: the substrate layer is thicker than the electronics layer, the substrate layer extends to a bottom surface of the semiconductor wafer and the electronics layer extends to a top surface of the semiconductor wafer;
forming a handle wafer separate from the semiconductor wafer;
attaching the top surface of the semiconductor wafer to a top surface of the handle wafer;
removing the substrate layer from the semiconductor wafer;
forming a glass cover layer over the bottom surface of the semiconductor wafer;
flipping the semiconductor wafer so that a bottom surface of the handle wafer is exposed for processing; and
using the glass cover layer to provide mechanical support for the semiconductor wafer, removing the handle wafer from the semiconductor wafer.

9. The method of manufacturing a thin semiconductor device of claim 8, further comprising the steps of:
removing an adhesive bond used to attach the top surface of the semiconductor wafer to the top surface of the handle wafer to expose a plurality of contacts of the semiconductor wafer; and
using an electrolytic plating process, forming conductive traces, each conductive trace being electrically coupled to a respective one of the plurality of contacts.

10. The method of manufacturing a thin semiconductor device of claim 8, further comprising the steps of:
removing an adhesive bond used to attach the top surface of the semiconductor wafer to the top surface of the handle wafer to expose a plurality of contacts from the semiconductor wafer;
forming a thick polymer coating on the top surface of the semiconductor wafer; and
forming and filling with a conductive material, a plurality of via holes in the thick polymer coating.

11. The method of manufacturing a thin semiconductor device of claim 8, further comprising the step of:
forming a smart cut fault line in the handle wafer separating a majority portion of the handle wafer from a minority portion of the handle wafer before attaching the minority portion of the handle wafer to the semiconductor wafer,
wherein the step of removing the handle wafer from the semiconductor wafer includes separating the majority portion from the minority portion at the fault line and removing the minority portion from the semiconductor wafer.

12. The method of manufacturing a thin semiconductor device of claim 11,
wherein the smart cut fault line is formed in the handle wafer by:
bombarding the handle wafer with ions to implant the ions in the handle wafer while maintaining the handle wafer at a first temperature; and
heat treating the handle wafer at a second temperature greater than the first temperature, to define a separation between the a majority portion of the handle wafer and a minority portion of the handle wafer.

13. The method of manufacturing a thin semiconductor device of claim 12, wherein the first temperature is lower than a temperature at which the implanted ions may escape from the handle wafer by diffusion.

14. The method of manufacturing a thin semiconductor device of claim 11,
wherein the smart cut fault line is formed in the handle wafer by focusing an infrared laser at a point beneath the top surface of the handle wafer and scanning the focused laser across the top surface of the handle wafer.

15. The method of manufacturing a thin semiconductor device of claim 8, wherein the step of attaching the top surface of the semiconductor wafer to the top surface of the handle wafer includes applying a temporary adhesive to at least one of the top surfaces of the semiconductor wafer and the top surface of the handle wafer and the step of removing the adhesive bond includes sliding the semiconductor wafer relative to the handle wafer to break the bond and dissolving any of the temporary adhesive on the semiconductor wafer.

16. The method of manufacturing a thin semiconductor device of claim 8, further comprising the steps of:
forming a color filter array on a surface of the semiconductor wafer remaining after the substrate is removed;
forming a microlens array over the color filter array,
wherein a cavity is formed between a top surface of the color filter array and a bottom surface of the cover glass when the cover glass is formed over the color filter array.

17. The method of manufacturing a thin semiconductor device of claim 16, further comprising the step of:
filling the cavity with an optical gap fill material having an index of refraction less than an index of refraction of the cover glass and less than an index of refraction of the microlenses.

18. The method of manufacturing a thin semiconductor device of claim 16, further comprising the step of:
forming a passivation layer on the color filter array,
wherein the cover glass is formed over the color filter array by attaching the cover glass to the passivation layer.

19. The method of manufacturing a thin semiconductor device of claim 16,
wherein the step of attaching the semiconductor wafer to the handle wafer includes the steps of applying an adhesive to at least one of the semiconductor wafer and the handle wafer and pressing the semiconductor wafer and handle wafer together,
wherein the cover glass is permanently attached to passivation layer using an adhesive having different material properties than the adhesive used to attach the top surface of the semiconductor wafer to the top surface of the handle wafer.

20. A back illuminated imager comprising:
a semiconductor wafer including a plurality of image sensing elements configured to receive light through a back side of the wafer;
a plurality of lenses disposed above the back side of the wafer such that an air gap is formed between the plurality of lenses and the back side of the wafer;
a cover glass attached to the back side of the wafer such that the cover glass is disposed above the plurality of lenses and the air gap; and
a plurality of electrical contacts formed on a front side of the wafer.

21. The back illuminated imager of claim 20, further comprising a thick polymer coating disposed directly on the front side of the wafer.

22. The back illuminated imager of claim 21, further comprising a plurality of color filters disposed directly on the back side of the wafer.

23. The back illuminated imager of claim 20, wherein the semiconductor wafer has a thickness of between 1.5 and 15 microns.

24. A back illuminated imager comprising:
a semiconductor wafer including a plurality of image sensing elements configured to receive light through a back side of the wafer;
a plurality of electrical contacts formed on the front side of the wafer;
a handle wafer permanently bonded to the semiconductor wafer, the handle wafer having formed through it a plurality of vias, each via corresponding to a respective one of the plurality of electrical contacts and filled with a conductive material.

25. The back illuminated imager of claim 24, wherein the semiconductor wafer has a thickness of between 1.5 and 15 microns.
